(19) United States
(12) Patent Application Publication
(10) Pub. No.: US 2025/0176318 A1
(43) Pub. Date: May 29, 2025

(54) LIGHT EMITTING DIODE AND LIGHT EMITTING DEVICE

(71) Applicant: XIAMEN SAN'AN OPTOELECTRONICS CO., LTD., Xiamen (CN)

(72) Inventors: Xiushan ZHU, Xiamen (CN); Yan LI, Xiamen (CN); Qi JING, Xiamen (CN); Zhihao BAO, Xiamen (CN); Qingchao YANG, Xiamen (CN); Chunhsien LEE, Xiamen (CN); Chi-Ming TSAI, Xiamen (CN); Juchin TU, Xiamen (CN); Chung-Ying CHANG, Xiamen (CN)

(21) Appl. No.: 18/953,104

(22) Filed: Nov. 20, 2024

(30) Foreign Application Priority Data
Nov. 23, 2023 (CN) 2023115759165

(51) Int. Cl. H01L 33/38; H01L 33/20; H01L 33/42; H01L 33/46; H01L 33/62

(52) U.S. Cl. CPC H10H 20/831; H10H 20/819; H10H 20/833; H10H 20/841; H10H 20/857

(57) ABSTRACT

A light emitting diode includes a semiconductor stacked layer, including a first semiconductor layer, a light-emitting layer and a second semiconductor layer sequentially stacked in that order, and having a mesa being an upper surface of the first semiconductor layer that is not covered by the light-emitting layer; and an insulation structure, covering the semiconductor stacked layer, and having a first opening located on the mesa and a second opening located on the second semiconductor layer. The semiconductor stacked layer defines a dimple at the mesa. The first semiconductor layer has a first sloped sidewall at the dimple, the insulation structure has a second sloped sidewall at the mesa, an angle between the first sloped sidewall and a horizontal plane is first angle, an angle between the second sloped sidewall and the horizontal plane is second angle, and the first angle is smaller than or equal to the second angle.

### CROSS REFERENCE TO RELATED APPLICATION

This application claims priority to Chinese Patent Application No. 202311575916.5, filed on Nov. 23, 2023, which is herein incorporated by reference in its entirety.

### TECHNICAL FIELD

The disclosure relates to the field of semiconductor manufacturing technologies, and more particularly to a light emitting diode and a light emitting device.

### BACKGROUND

Light emitting diode (LED) is a semiconductor light emitting element, and is generally manufactured by gallium nitride (GaN), gallium arsenide (GaAs), gallium phosphide (GaP), and gallium arsenide phosphide (GaAsP). A core of the LED is a PN junction with light emitting characteristics. LED has advantages of large light emitting intensity, high efficiency, small volume and long service life, which is considered as one of the most promising light sources at present. LED has been widely used in lighting, monitoring and command, high-definition broadcasting, high-end cinemas, office displays, conference interaction, virtual reality and other fields.

In the application field of mini red green blue (RGB) flip chips, and manufacturers have a higher demand for the mini RGB flip chips. Since the mini RGB flip chips have small size, antistatic ability of the chips is usually weak and the light emitting brightness of the chips is not high, which cannot meet the current usage requirements. Therefore, how to improve antistatic performance and light emitting performance of a mini LED has become one of the problems to be solved in this field.

It should be noted that information disclosed in the background section is only intended to increase the understanding of the overall background of the disclosure, and should not be regarded as admitting or suggesting in any form that the information constitutes related art already known to those skilled in the art.

### SUMMARY

The disclosure provides a light emitting diode, including a semiconductor stacked layer and an insulation structure.

The semiconductor stacked layer includes a first semiconductor layer, a light emitting layer and a second semiconductor layer sequentially stacked in that order. The semiconductor stacked layer has a mesa, and the mesa is an upper surface of the first semiconductor layer not covered by the light emitting layer. The insulation structure covers the semiconductor stacked layer, and is defined with a first opening and a second opening. The first opening is located on the mesa, and the second opening is located on the second semiconductor layer. The semiconductor stacked layer defines a dimple at the mesa. The first semiconductor layer has a first sloped sidewall at the dimple, and the insulation structure has a second sloped sidewall at the mesa. An angle between the first sloped sidewall and a horizontal plane is a first angle, an angle between the second sloped sidewall and the horizontal plane is a second angle, and the first angle is smaller than or equal to the second angle.

The disclosure further provides a light emitting device, which adopts the light emitting diode provided by the above embodiment.

In the light emitting diode and the light emitting device provided in the embodiment of the disclosure, the dimple is defined at the mesa of the first semiconductor layer, and the first angle of the first sloped sidewall is designed to be smaller than or equal to the second angle of the second sloped sidewall, so as to ensure an antistatic performance and a light emitting performance of the light emitting diode, and improve reliability of the light emitting device.

Other features and beneficial effects of the disclosure will be described in the following description, and some of the technical features and beneficial effects can be obviously derived from the description or understood by implementing the disclosure.

### BRIEF DESCRIPTION OF DRAWINGS

In order to more clearly describe technical solutions in embodiments of the disclosure or in the related art, drawings required in descriptions of the embodiments or the related art are simply introduced below. Apparently, some of the drawings described below are some of the embodiments of the disclosure. For those skilled in the art, other drawings can be obtained based on these drawings without creative work.

FIG. 1 illustrates a schematic structural diagram of a light emitting diode according to an embodiment of the disclosure.

FIG. 2 illustrates a schematic partially enlarged diagram of an area A in FIG. 1.

FIG. 3 illustrates a schematic structural diagram of a traditional light emitting diode.

FIG. 4 illustrates a schematic structural diagram of a traditional light emitting diode.

FIG. 5 illustrates a schematic structural diagram of the light emitting diode in a stage of defining a dimple according to an embodiment of the disclosure.

FIG. 6 illustrates a schematic structural diagram of the light emitting diode in a stage of defining the dimple according to an embodiment of the disclosure.

### DESCRIPTION OF REFERENCE SIGNS

10—substrate; 12—semiconductor stacked layer; 121—first semiconductor layer; 122—light emitting layer; 123—second semiconductor layer; 124—mesa; 14—insulation structure; 141—first opening; 142—second opening; 16—dimple; 21—first sloped sidewall; 22—second sloped sidewall; 23—third sloped sidewall; 30—transparent conductive layer; 31—first pad electrode; 32—second pad electrode; M1—first angle; M2—second angle; M3—third angle; M4—fourth angle; H1—depth of dimple.

### DETAILED DESCRIPTION OF EMBODIMENTS

In order to make purpose, technical solutions and advantages of embodiments of the disclosure clearer, the technical solutions in the embodiments of the disclosure will be clearly and completely described below in conjunction with drawings in the embodiments of the disclosure. Apparently, the described embodiments are some of the embodiments of the disclosure, rather than all of them. The technical features designed in different embodiments of the disclosure described below can be combined with each other as long as they do not conflict with each other. Based on the embodiments of the disclosure, all other embodiments obtained by those skilled in the art without creative work are within a scope of protection of the disclosure.

In the description of the disclosure, it should be understood that terms “center”, “lateral”, “up”, “down”, “left”, “right”, “vertical”, “horizontal”, “top”, “bottom”, “inside”, “outside” and the like indicate positions or positional relationships based on the positions or positional relationships shown in the drawings, and are only for the convenience of describing the disclosure and simplifying the description, rather than indicating or implying that the device or component referred to must have a specific orientation, or be constructed and operated in a specific orientation, and therefore cannot be understood as a limitation on the disclosure. In addition, terms “first” and “second” are used for descriptive purposes only, and cannot be understood as indicating or implying relative importance or implicitly indicating the number of technical features indicated. Thus, the features defined as “first” and “second” may explicitly or implicitly include one or more of the features. In the description of the disclosure, unless otherwise specified, “multiple” means two or more. In addition, the term “including” and any variation thereof all mean “at least including”.

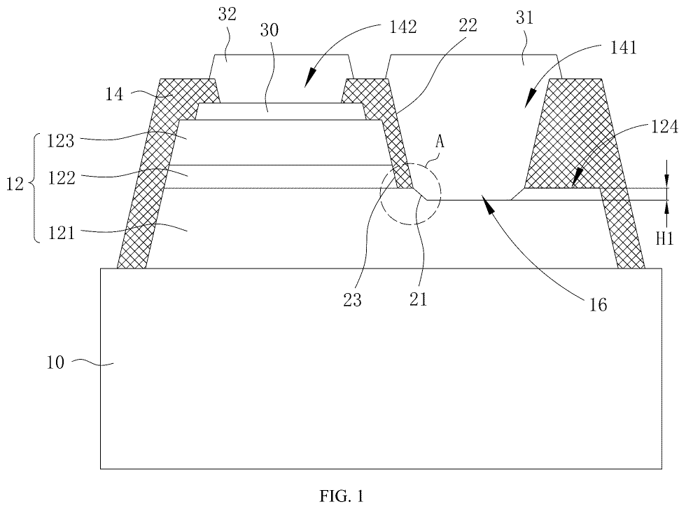

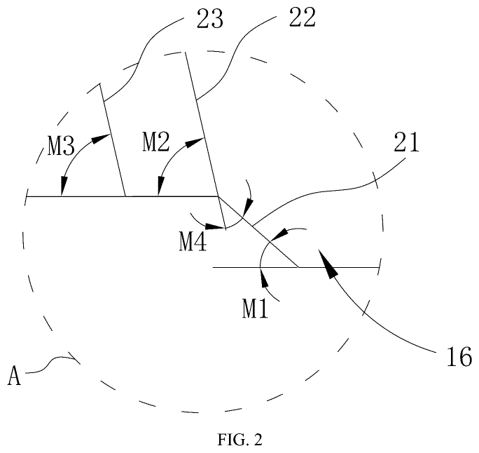

Referring to FIG. 1 and FIG. 2, FIG. 1 illustrates a schematic structural diagram of a light emitting diode according to an embodiment of the disclosure, and FIG. 2 illustrates a schematic partially enlarged diagram of an area A in FIG. 1. In order to achieve at least one of the above advantages or other advantages, an embodiment of the disclosure provides a light emitting diode. As shown in FIG. 1, the light emitting diode includes a semiconductor stacked layer 12 and an insulation structure 14.

The semiconductor stacked layer 12 is disposed on a substrate 10. The substrate 10 may be an insulation substrate, in an embodiment, the substrate 10 may be made of a transparent material or a semitransparent material (also referred to as translucent material). In the embodiment illustrated by FIG. 1, the substrate 10 is a sapphire substrate. In some embodiments, the substrate 10 may be a patterned sapphire substrate, but the disclosure is not limited to this. The substrate 10 may be also made of a conductive material or a semiconductive material. For example, a material of the substrate 10 includes at least one selected from the group consisting of silicon carbide (SiC), silicon (Si), magnesium aluminum oxide, magnesium oxide, lithium aluminum oxide, aluminum gallium oxide, and gallium nitride (GaN).

The semiconductor stacked layer 12 includes a first semiconductor layer 121, a light emitting layer 122 and a second semiconductor layer 123 sequentially stacked in that order. The semiconductor stacked layer 12 has a mesa 124, and the mesa 124 is an upper surface of the first semiconductor layer 121 that is not covered by the light emitting layer 122. In some embodiments, the second semiconductor layer 123 and the light emitting layer 122 are removed from partial area of the semiconductor stacked layer 12 to expose the first semiconductor layer 121, to thereby form one or more mesas 124. That is, the mesa 124 is the upper surface of the first semiconductor layer 121 that is not covered by the second semiconductor layer 123 and the light emitting layer 122. As shown in FIG. 1, the mesa 124 is used to dispose a first pad electrode 31. The distribution of the mesa 124 is not limited to that shown in FIG. 1, and can be designed according to actual size and shape of the chip. The mesa 124 may be connected together, or separated from each other.

The first semiconductor layer 121 may be a N-type semiconductor layer, which can provide electrons to the light emitting layer 122 under an action of a power source. In some embodiments, the first semiconductor layer 121 includes a N-type doped nitride layer. The N-type doped nitride layer may include N-type impurities. The N-type impurities may include one of silicon (Si), germanium (Ge) and tin (Sn) or a combination thereof.

The light emitting layer 122 may be a quantum well (QW) structure. In some embodiments, the light emitting layer 122 may also be a multiple quantum well (MQW) structure, and the MQW structure includes MQW layers and multiple quantum barrier layers that are repeatedly and alternatively arranged. For example, it may be a MQW structure of gallium nitride/aluminum gallium nitride (GaN/AlGaN), indium aluminum gallium nitride/aluminum gallium nitride (InAlGaN/AlGaN) or indium gallium nitride/aluminum gallium nitride (InGaN/AlGaN). In addition, the composition and thickness of the well layers in the light emitting layer 122 determine the wavelength of the generated light. In order to improve light emitting efficiency of the light emitting layer 122, it can be achieved by changing the depth of the QW, the number of layers, thickness and/or other characteristics of the paired QW and quantum barriers in the light emitting layer 122.

The second semiconductor layer 123 may be a P-type semiconductor layer, which can provide holes to the light emitting layer 122 under the action of the power source. In some embodiments, the second semiconductor layer 123 includes a P-type doped nitride layer. The P-type doped nitride layer may include one or more P-type impurities. The P-type impurities may be one of magnesium (Mg), zinc (Zn) and beryllium (Be) or a combination thereof. The second semiconductor layer 123 may be a single-layer structure, can also be a multilayer structure, and the multilayer structure has different compositions.

The insulation layer 14 covers the semiconductor stacked layer 12, and is defined with a first opening 141 and a second opening 142. The first opening 141 is located on the mesa 124, and the second opening 142 is located on the second semiconductor layer 123. The insulation structure 14 is made of non-conductive materials. The non-conductive materials are inorganic materials or dielectric materials. The inorganic materials may include silicone. The dielectric materials may include electrically insulating materials such as aluminum oxide, silicon nitride, silicon oxide, titanium oxide, and magnesium fluoride. For example, the insulation structure 14 may be made of silicon dioxide, silicon nitride, titanium oxide, tantalum oxide, niobium oxide, barium titanate or a combination thereof, and the combination may be a distributed Bragg reflector (DBR) formed by repeatedly stacking two materials with different refractive indexes.

The semiconductor stacked layer 12 defines a dimple 16 at the mesa 124, and the dimple 16 is concaved from the upper surface of the first semiconductor layer 121 to a lower surface of the first semiconductor layer 121. A depth H1 of the dimple 16 is in a range of 1000 angstroms (Å) to 4000 Å. The first semiconductor layer 121 has a first sloped sidewall 21 at the dimple 16, the insulation structure 14 has a second sloped sidewall 22 at the mesa 124, and a sloped degree of the first sloped sidewall 21 is different from that of the second sloped sidewall 22. Specifically, an angle between the first sloped sidewall 21 and a horizontal plane is a first angle M1, an angle between the second sloped sidewall 22 and the horizontal plane is a second angle M2, and the first angle M1 and the second angle M2 are acute angles smaller than 90 degrees. The first angle M1 is smaller than or equal to the second angle M2. By setting this, the antistatic performance and light emitting performance of the light emitting diode can be guaranteed, and the reliability of the light emitting device can be improved. In some embodiments, the first angle M1 is smaller than the second angle M2, so that the insulation structure 14 covers the first semiconductor layer 121 better.

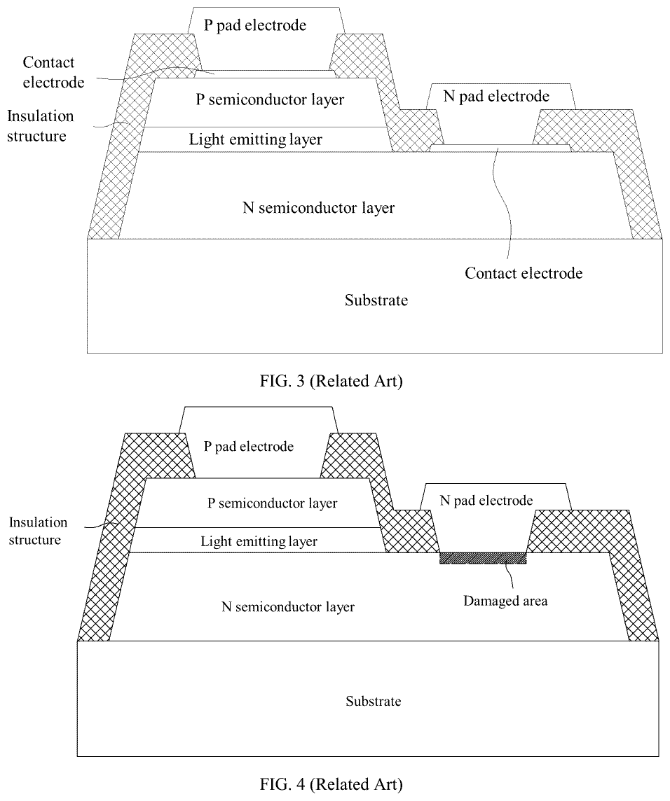

A traditional mini RGB flip chip is shown in FIG. 3. In the earliest mini LED chip, a N semiconductor layer is formed above the substrate, the N semiconductor layer has an exposed mesa, a light emitting layer is adjacent to the mesa, a P semiconductor layer is located above the light emitting layer, and a contact electrode consisting of metal layers is formed above the P semiconductor layer and the N semiconductor layer with the mesa structure. After forming the contact electrode, an insulation structure covering the contact electrode and the mesa is formed. An opening is defined at a position corresponding to the contact electrode in the insulation structure, and an N pad electrode and a P pad electrode are formed on the insulation structure. Since the contact electrode only covers part of the N semiconductor layer and the P semiconductor layer, an edge part of the contact electrode has a sloped angle with the surface of the P semiconductor layer. Similarly, the edge part of the contact electrode also has a sloped angle with the surface of the N semiconductor layer. During the subsequent deposition of the insulation structure, due to the large number of layers and large thickness of the insulation structure, the existence of the sloped angle will cause the insulation structure to have corners and protrusions here, resulting in an uneven surface of the insulation structure. In addition, when defining an electrode through hole in the insulation structure, there will also be a sloped angle between the sidewall of the insulation structure and the surface of the contact electrode, so that when pad electrodes (such as N pad electrode and P pad electrode) are formed above the contact electrode, the aforementioned corners, protrusions and the sloped angle of the sidewall of the electrode through hole will cause the material coverage of the pad electrodes to deteriorate, resulting in defects such as fractures or cracks, thereby reducing the reliability of the light emitting device. In addition, due to the corners and protrusions of the insulation structure, protrusions will also appear on the pad electrodes, resulting in an uneven surface of the light emitting device. In the later die bonding process, the height difference on the device surface will cause poor die bonding, which affects the reliability of the light emitting device.

Subsequently, as shown in FIG. 4, in order to solve the problem of the mini LED chip in FIG. 3, the contact electrode is usually removed, and the insulation structure is directly processed by using an inductively coupled plasma (ICP) dry etching method to directly define two openings (such as the first opening 141 and the second opening 142 in the embodiment), and then the N pad electrode and the P pad electrode are directly connected to the N semiconductor layer and the P semiconductor layer respectively through the openings. However, in the process of defining the openings by using the ICP dry etching method, the surface of the N semiconductor layer at the openings will be damaged to form a damaged area (in the ICP process, the gas will react with the N semiconductor layer to cause the N semiconductor layer to be damaged, thereby forming a high-resistance reaction product, and forming the damaged area on the surface of the N semiconductor layer), and the damaged area is roughly indicated by its location area in the manner of shadow filling. The damaged area will affect the overall performance of the chip, such as reducing the antistatic performance and light emitting performance of the chip.

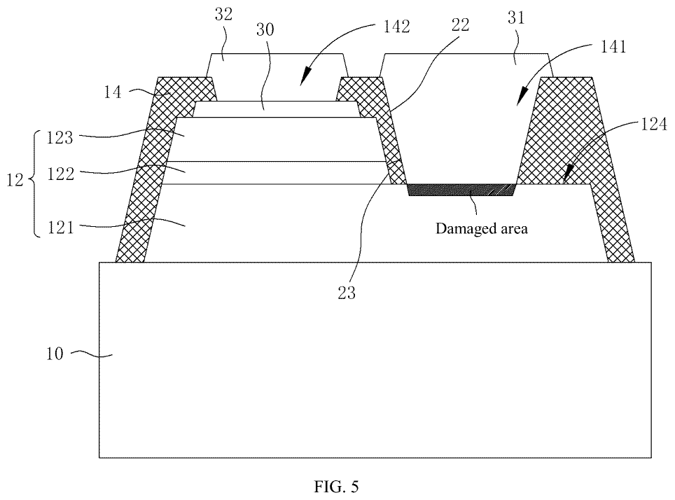

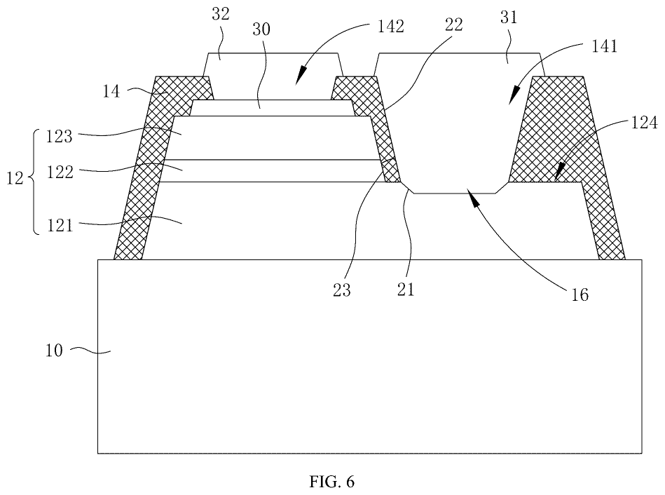

Therefore, the embodiment solves the problem by adding a process aiming at the damaged area. For example, the damaged area can be treated by adding an additional ICP dry etching process, and the etching rates of the insulation structure 14 and the first semiconductor layer 121 in the ICP process are inconsistent (due to different materials resulting in different etching rates), thereby forming the dimple 16 and the first sloped sidewall 21, and the first sloped sidewall 21 and the second sloped sidewall 22 have different sloped degrees. Specifically, the first opening 141 and the dimple 16 are defined separately through two etching steps. First, as shown in FIG. 5, in the first etching process, the insulation structure 14 is etched to define the first opening 141 and the second opening 142. However, at this time, the etching gas (i.e., etching medium) inevitably damages the first semiconductor layer 121, that is, a damaged area is formed on the surface of the first semiconductor layer 121 at the first opening 141. Subsequently, as shown in FIG. 6, a second etching is performed. The etching gas is replaced with an etching gas specifically for removing the damaged area on the surface of the first semiconductor layer 121. At this time, the insulation structure 14 will hardly be affected by the replaced etching gas, thus the insulation structure 14 will hardly be etched. The etching depth, angle, area, and the like can be controlled by controlling the time and amount of the etching gas adapted to the material of the first semiconductor layer 121. Therefore, the dimple 16 formed by the second etching can be deeper to remove the damaged area as much as possible and increase the contact area of the pad electrodes. In addition, in theory, the angle of the first angle M1 can be set to any size, however, when considering the coverage effect of the pad electrodes and taking into account the effective light emitting area, the first angle M1 cannot be too steep. Meanwhile, in order to better remove the damaged area, the first angle M1 cannot be too flat.

It should be noted that when only one etching step is used, although an area similar to the dimple 16 can be formed by over-etching, since the gas of the first etching is used to etch the insulation structure 14 to define the openings, the medium of the first etching (i.e., the etching gas) will continue to damage the first semiconductor layer. That is, in the process of etching away the damaged area, new damaged areas will be generated. Thus, the actual technical problem cannot be solved, and the formation of the dimple 16 is unavoidable in the first etching. Therefore, it is impossible to control the depth, angle, size, and the like of the dimple 16 etched in the first semiconductor layer, which is not conducive to ensuring the overall performance.

In some embodiments, a longitudinal cross section of the dimple 16 is inverted trapezoidal, which has better effects for ensuring the antistatic performance and the light emitting performance of the chip. In an embodiment, a range of the first angle M1 is 10° to 45°. When the first angle M1 is too small (such as smaller than 10°), the removed part is too less, which cannot effectively remove the damaged area, resulting in the chip performance still being damaged to a certain extent. When the first angle M1 is too large (such as greater than 45°), a normal part of the first semiconductor layer 121 will be excessively removed, which makes the area of the dimple 16 too large, causes the effective light emitting area to become smaller, and is not conducive to the overall light emitting performance. In an embodiment, a range of the second angle M2 is 45° to 70°. When the second angle M2 is too small (such as smaller than 45°), it may not be possible to leave more space for the dimple 16, resulting in the chip performance still being damaged to a certain extent. When the second angle M2 is too large (such as greater than 70°), a relatively vertical sidewall will be formed, which is not conducive to the subsequent coverage of the electrode material and affects the performance of the light emitting diode.

The semiconductor stacked layer 12 further has a third sloped sidewall 23. An upper end and a lower end of the third sloped sidewall 23 are respectively connected to an upper surface of the second semiconductor layer 123 and a lower surface of the light emitting layer 122, and an angle between the third sloped sidewall 23 and the horizontal plane is a third angle M3. The third angle M3 is smaller than the second angle M2, so that the insulation structure 14 can cover the third sloped sidewall 23 better to avoid adverse situations such as breakage. A range of the third angle M3 may be 30° to 50°, or may be 30° to 40°. In some embodiments, the third angle M3 is greater than the first angle M1, so that the repair of the first semiconductor layer 121 is more sufficient, and the antistatic performance and the light emitting performance of the chip are further guaranteed.

In some embodiments, the semiconductor stacked layer 12 further has a fourth angle M4, an angle of the second angle M2 minus the first angle M1 is the fourth angle M4, and a range of the fourth angle M4 is 0° to 60°. The fourth angle M4 can objectively reflect the degree of concavity of the dimple 16, and can also reflect the degree of repair of the damaged area. When the fourth angle M4 is 0°, the first angle M1 and the second angle M2 are equal.

The light emitting diode further includes a transparent conductive layer 30, a first pad electrode 31 and a second pad electrode 32.

The first pad electrode 31 is connected to the first semiconductor layer 121 through the first opening 141. The first pad electrode 31 may be made of metal materials. The first pad electrode 31 may be a single-layer structure, a dual-layer structure or a multilayer structure, such as: titanium (Ti)/aluminium (Al), Ti/Al/Ti/Au, Ti/Al/nickel (Ni)/Au, vanadium (V)/Al/platinum (Pt)/Au and other metal stacked structures.

The second pad electrode 32 is connected to the second semiconductor layer 123 through the second opening 142. The second pad electrode 32 may be made of metal materials. The second pad electrode 32 may be a single-layer structure, a dual-layer structure or a multilayer structure, such as: Ti/Al, Ti/Al/Ti/Au, Ti/Al/Ni/Au, V/Al/Pt/Au and other metal stacked structures.

The transparent conductive layer 30 is located between the second pad electrode 32 and the second semiconductor layer 123, and is used to improve current diffusion, to further enhance the light emitting performance of the light emitting diode. The transparent conductive layer 30 may be made from transparent conductive materials, and the transparent conductive materials may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiment of the disclosure is limited to this.

In some embodiments, the light emitting diode is a flip chip light emitting diode. The light emitting diode is a mini LED with a small size, and a side length of the light emitting diode is smaller than 100 microns (m).

The disclosure further provides a light emitting device, which adopts the light emitting diode provided by any one of the aforementioned embodiments.

Table 1 illustrates a comparison of yields of the traditional LED and the LED of the disclosure under voltages of 2000 volts (V), 3000 V, 4000 V and 4500 V. As shown in Table 1, the LED of the disclosure has high yield compared to the traditional LED under a higher electrostatic discharge (ESD), which indicates that the LED of the disclosure can effectively improve the antistatic performance of itself.

TABLE 1

| | 2000 V | 3000 V | 4000 V | 4500 V |
|---|---|---|---|---|
| Traditional LED | 99.6% | 99.1% | 3.9% | 0% |
| LED of the disclosure | 100% | 100% | 82.6% | 25.3% |

The embodiment of the disclosure provides the light emitting diode and the light emitting device, which ensure the antistatic performance and the light emitting performance of the light emitting diode and improve the reliability of the device by defining the dimple 16 at the mesa 124 of the first semiconductor layer 121 and controlling the first angle M1 of the first sloped sidewall 21 to be smaller than or equal to the second angle M2 of the second sloped sidewall 22.

In addition, those skilled in the art should understand that, although there are many problems in the related art, each embodiment or technical solution of the disclosure can be improved in only one or several aspects, without having to solve all the technical problems listed in the related art or background technology at the same time. Those skilled in the art should understand that the content not mentioned in a claim should not be used as a limitation on the claim.

Finally, it should be noted that the above embodiments are only used to illustrate the technical solutions of the disclosure, rather than to limit it. Although the disclosure has been described in detail with reference to the aforementioned embodiments, those skilled in the art should understand that they can still modify the technical solutions described in the aforementioned embodiments, or replace some or all of the technical features therein with equivalents. However, these modifications or replacements do not cause the essence of the corresponding technical solutions to deviate from the scope of the technical solutions of the embodiments of the disclosure.

What is claimed is:

1. A light emitting diode, comprising:
a semiconductor stacked layer, comprising: a first semiconductor layer, a light emitting layer and a second semiconductor layer sequentially stacked in that order; wherein the semiconductor stacked layer has a mesa, and the mesa is an upper surface of the first semiconductor layer not covered by the light emitting layer; and
an insulation structure, covering the semiconductor stacked layer, and defined with a first opening and a second opening; wherein the first opening is located on the mesa, and the second opening is located on the second semiconductor layer; and
wherein the semiconductor stacked layer defines a dimple at the mesa, the first semiconductor layer has a first sloped sidewall at the dimple, the insulation structure has a second sloped sidewall at the mesa, an angle between the first sloped sidewall and a horizontal plane is a first angle, an angle between the second sloped sidewall and the horizontal plane is a second angle, and the first angle is smaller than or equal to the second angle.

2. The light emitting diode as claimed in claim 1, wherein the first angle is in a range of 10° to 45°.

3. The light emitting diode as claimed in claim 1, wherein the second angle is in a range of 45° to 70°.

4. The light emitting diode as claimed in claim 1, wherein the dimple is concaved from the upper surface of the first semiconductor layer to a lower surface of the first semiconductor layer.

5. The light emitting diode as claimed in claim 1, wherein a depth of the dimple is in a range of 1000 Å to 4000 Å.

6. The light emitting diode as claimed in claim 1, wherein the semiconductor stacked layer has a third sloped sidewall, an upper end and a lower end of the third sloped sidewall are respectively connected to an upper surface of the second semiconductor layer and a lower surface of the light emitting layer, an angle between the third sloped sidewall and the horizontal plane is a third angle, and the third angle is smaller than the second angle.

7. The light emitting diode as claimed in claim 6, wherein the third angle is in a range of 30° to 50°.

8. The light emitting diode as claimed in claim 6, wherein the third angle is greater than the first angle.

9. The light emitting diode as claimed in claim 1, further comprising:
a first pad electrode, connected to the first semiconductor layer through the first opening; and
a second pad electrode, connected to the second semiconductor layer through the second opening.

10. The light emitting diode as claimed in claim 1, further comprising: a transparent conductive layer, located between the second pad electrode and the second semiconductor layer.

11. The light emitting diode as claimed in claim 1, wherein a longitudinal cross section of the dimple is inverted trapezoidal.

12. The light emitting diode as claimed in claim 1, wherein the light emitting diode is a flip chip light emitting diode.

13. The light emitting diode as claimed in claim 1, wherein a side length of the light emitting diode is smaller than 100 km.

14. The light emitting diode as claimed in claim 1, wherein the first opening and the dimple are defined by two etching steps respectively.

15. The light emitting diode as claimed in claim 1, wherein an angle of the second angle minus the first angle is a fourth angle, and the fourth angle is in a range of 0° to 60°.

16. The light emitting diode as claimed in claim 1, further comprising: a substrate; wherein the semiconductor stacked layer is disposed on the substrate, and a material of the substrate comprises at least one selected from the group consisting of silicon carbide, silicon, magnesium aluminum oxide, magnesium oxide, lithium aluminum oxide, aluminum gallium oxide, and gallium nitride.

17. The light emitting diode as claimed in claim 1, wherein the insulation structure is a distributed Bragg reflector (DBR) formed by repeatedly stacking two materials with different refractive indexes.

18. The light emitting diode as claimed in claim 10, wherein a material of the transparent conductive layer comprises at least one selected from the group consisting of indium tin oxide, indium zinc oxide, indium oxide, tin oxide, cadmium tin oxide, antimony tin oxide, aluminum zinc oxide, zinc tin oxide, gallium doped zinc oxide, tungsten doped indium oxide, and zinc oxide.

19. The light emitting diode as claimed in claim 6, wherein the third angle is in a range of 30° to 40°.

20. A light emitting device, comprising: the light emitting diode as claimed in claim 1.
